(19) United States
(12) Patent Application Publication
(10) Pub. No.: US 2009/0160559 A1
(43) Pub. Date: Jun. 25, 2009

(54) INTEGRATED CIRCUIT INCLUDING IMPEDANCE TO PROVIDE SYMMETRICAL DIFFERENTIAL SIGNALS

(76) Inventors: Luca Ravezzi, Palo Alto, CA (US); Hamid Partovi, Los Altos, CA (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/960,036

(22) Filed: Dec. 19, 2007

(51) Int. Cl. H03F 3/04

(52) U.S. Cl. 330/301

(57) ABSTRACT

One embodiment provides an integrated circuit including an input stage and an impedance. The input stage is configured to receive a single-ended input signal and provide a differential output signal. The impedance is configured to receive the single-ended input signal and provide compensation to the input stage to provide symmetrical differential signals in the differential output signal.

### BACKGROUND

Typically, an electrical system includes a number of circuits that communicate with one another to perform system functions. The circuits can be on the same integrated circuit chip or on separate integrated circuit chips.

Often, an electrical system includes one or more controllers, such as a micro-processor, and one or more memory devices, such as random access memory (RAM) devices. The RAM can be any suitable type of RAM, such as dynamic RAM (DRAM), double data rate synchronous DRAM (DDR-SDRAM), and graphics DDR-SDRAM (GDDR-SDRAM). Also, the RAM can be any suitable generation, such as second or third generation DDR-SDRAM and third, fourth, or fifth generation GDDR-SDRAM.

In some electrical systems, the circuits communicate via single-ended signals and differential signals. Single-ended signals carry the same amount of data as differential signals and can be used to reduce the number of communication lines. Sometimes, single-ended signals are converted to differential signals, which may be done to increase noise immunity. In these situations, a single-ended to differential signal converter is needed to convert a single-ended input signal to a differential output signal, without introducing time distortion into the differential output signal.

Some single-ended to differential signal converters have a differential pair of transistors having one input connected to a single-ended input signal and the other input connected to a reference signal. If the single-ended input signal is a small signal, the circuit operates in a quasi-linear region. However, if the single-ended input signal is not a small signal, but varies greatly, such as when amplitude, slope, and/or frequency change more than an order of magnitude, the circuit does not operate in the quasi-linear region. Instead, the circuit operates in non-linear regions, where asymmetrically driving the inputs causes variations in the output common-mode signal to be converted into the differential output signal. In addition, asymmetrically driving the inputs combined with parasitic impedances and non-linear operation of the circuit introduces time distortion, i.e. jitter, into the differential output signal, which limits the performance of the single-ended to differential signal converter in high-speed applications.

For these and other reasons there is a need for the present invention.

### SUMMARY

The present disclosure describes an integrated circuit including an impedance that provides compensation to provide symmetrical differential signals. One embodiment provides an integrated circuit including an input stage and an impedance. The input stage is configured to receive a single-ended input signal and provide a differential output signal. The impedance is configured to receive the single-ended input signal and provide compensation to the input stage to provide symmetrical differential signals in the differential output signal.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an electrical system.

FIG. 2 is a diagram illustrating one embodiment of a single-ended to differential signal converter.

FIG. 3 is a diagram illustrating a small signal circuit that is a small signal model of the converter of FIG. 2.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

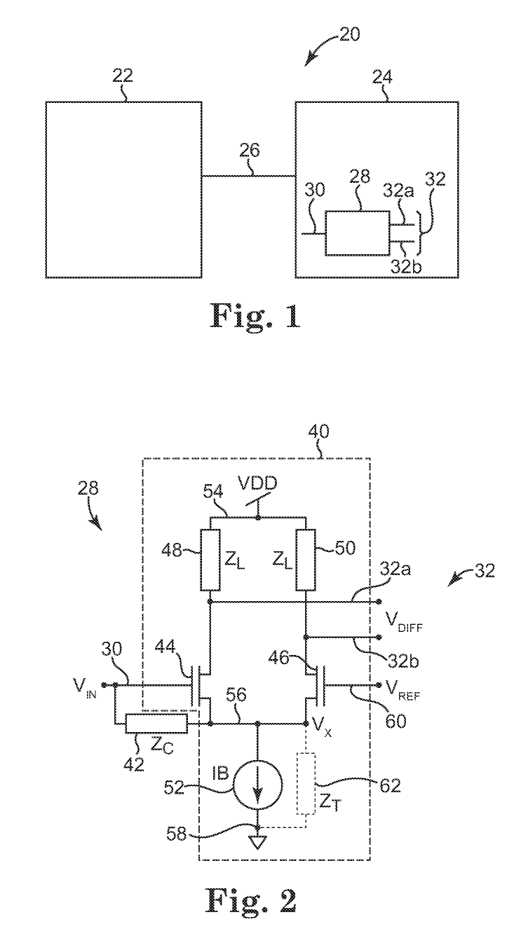

FIG. 1 is a block diagram illustrating one embodiment of an electrical system 20. Electrical system 20 includes a first integrated circuit chip 22 and a second integrated circuit chip 24. Chip 22 is electrically coupled to chip 24 via communications path 26. Chip 22 and chip 24 communicate via communications path 26 to perform system functions in system 20. In one embodiment, chip 22 is a memory controller. In one embodiment, chip 24 is a DRAM, such as a DDR-SDRAM or a GDDR-SDRAM. In one embodiment, chip 24 is a buffer chip. In one embodiment, chip 24 is a memory controller. In other embodiments, chip 22 and chip 24 are suitable chips that communicate with one another.

Chip 24 includes a single-ended to differential signal converter 28 that receives a single-ended input signal via input line 30 and converts the single-ended input signal at 30 to a differential output signal that is provided on output lines 32a and 32b. In one embodiment, converter 28 is an input buffer that receives a single-ended input signal at 30 from chip 22 via communications path 26. In one embodiment, converter 28 receives a single-ended input signal at 30 from circuits in chip 24. In one embodiment, the differential output signal at 32 is used in chip 24. In one embodiment, the differential output signal at 32 is output from chip 24 to other integrated circuit chips in system 20.

Converter 28 includes an input stage that receives the single-ended input signal at 30 and provides the differential output signal at 32. Converter 28 includes an impedance, which receives the single-ended input signal at 30 and provides compensation to the input stage. Converter 28 provides substantially symmetrical differential signals in the differential output signal at 32. The compensation signal provided to the input stage via the impedance is based on the single-ended input signal at 30.

In one embodiment, the impedance receives the single-ended input signal at 30 and provides compensation to the input stage to nullify common-mode variations in the differential output signal at 32. In one embodiment, the impedance provides compensation to the input stage so the conversion from common-mode to the differential output signal at 32 is substantially equal to zero.

FIG. 2 is a diagram illustrating one embodiment of the single-ended to differential signal converter 28 (illustrated in FIG. 1). Converter 28 includes an input stage 40 and impedance 42. Input stage 40 receives a single-ended input signal VIN via input line 30 and provides a differential output signal VDIFF via output lines 32a and 32b. Impedance 42 receives the single-ended input signal VIN via input line 30 and provides compensation to input stage 40 to provide substantially symmetrical differential signals in the differential output signal VDIFF at 32.

Input stage 40 includes a differential pair of transistors 44 and 46, a first load impedance 48, a second load impedance 50, and a current source 52. The differential pair of transistors includes first transistor 44 and second transistor 46. Each of the transistors in the differential pair of transistors 44 and 46 is an n-channel metal oxide semiconductor (NMOS) transistor. In other embodiments, each of the transistors in the differential pair of transistors 44 and 46 can be another suitable transistor, such as a p-channel metal oxide semiconductor (PMOS) transistor or a bipolar junction transistor.

One end of first load impedance 48 and one end of second load impedance 50 are electrically coupled to power supply voltage VDD via supply line 54. The other end of first load impedance 48 is electrically coupled to one side of the drain-source path of first transistor 44 via first output line 32a, and the other end of second load impedance 50 is electrically coupled to one side of the drain-source path of second transistor 46 via second output line 32b. The other side of the drain-source path of first transistor 44 is electrically coupled to the other side of the drain-source path of second transistor 46 at a common-node via node line 56. Also, one side of current source 52 is electrically coupled to the common-node via node line 56 and the other side of current source 52 is electrically coupled to a reference, such as ground, at 58. Current source 52 includes current source impedance 62 between the common-node at 56 and the reference at 58.

The gate of first transistor 44 receives the single-ended input signal VIN via input line 30 and the gate of second transistor 46 receives reference voltage VREF via reference line 60. The reference voltage VREF at 60 is at a voltage level that is between the high and low voltage levels of the single-ended input signal VIN at 30. One end of impedance 42 receives the single-ended input signal VIN via input line 30 and the other end of impedance 42 is electrically coupled to the common-node via node line 56. Impedance 42 provides compensation to the common-node at 56 based on the single-ended input signal VIN at 30.

If impedance 42 is removed to leave an open circuit in its place, input stage 40 still functions as a single-ended to differential signal converter. The gate of first transistor 44 receives the single-ended input signal VIN at 30 and the gate of second transistor 46 receives reference voltage VREF at 60. As the single-ended input signal VIN at 30 goes high, first transistor 44 is biased on and second transistor 46 is biased off. Current source 52 sinks current IB that flows primarily through first impedance 48 and first transistor 44. The voltage on first output line 32a is less than the voltage on second output line 32b. As the single-ended input signal VIN at 30 goes low, first transistor 44 is biased off and second transistor 46 is biased on. Current source 52 sinks current IB that flows primarily through second impedance 50 and second transistor 46. The voltage on first output line 32a is greater than the voltage on second output line 32b. Thus, input stage 40 still functions as a single-ended to differential signal converter if impedance 42 is removed.

However, if impedance 42 is removed, input stage 40 functions as a single-ended to differential signal converter that provides asymmetric differential signals in differential output signal VDIFF at 32. The common-node voltage VX at 56 transitions more slowly to a higher voltage level as the single-ended input signal VIN at 30 goes high, if impedance 42 is removed. As a result, first transistor 44 is biased on very fast and second transistor 46 is biased off more slowly. Also, the common-node voltage VX at 56 transitions more slowly to a lower voltage level as the single-ended input signal VIN at 30 goes low. As a result, first transistor 44 is biased off very fast and second transistor 46 is biased on more slowly. The resulting differential signals in differential output signal VDIFF at 32 are asymmetric.

Asymmetrically driving input stage 40 in combination with impedance 62 and non-linear responses in input stage 40 provides variations of the output common-mode signal in differential output signal VDIFF at 32. Since impedance 62 is non-infinite, the common-mode gain AC is not equal to zero and the common-mode variations are converted into the differential output signal VDIFF at 32. As a result, amplitude and time distortions arise in the differential output signal VDIFF at 32.

Impedance 42 provides compensation to input stage 40, which cancels the amplitude and time distortions in differential output signal VDIFF at 32. Impedance 42 receives the single-ended input signal VIN at 30 and provides compensation to the common-node at 56 based on the single-ended input signal VIN at 30. The value of impedance 42 is chosen to make the common-mode gain AC equal to zero, which cancels the amplitude and time distortions in differential output signal 32. As a result, converter 28 provides symmetric differential signals in differential output signal VDIFF at 32.

From a small signal analysis, the value of impedance 42 that makes the common-mode gain AC equal to zero is given by Equation I.

Zc=ZT(1+2/(gm*rds)) Equation I

Where ZC is the value of impedance 42, ZT is the value of impedance 62, gm is the trans-conductance of each of the first and second transistors 44 and 46, and rds is the drain-source resistance of each of the first and second transistors 44 and 46. In one embodiment, impedance 42 tracks impedance 62 to minimize residual output distortion.

In one embodiment, the amplitude distortion is made negligible by using a current source 52 that has a very high, i.e. substantially infinite, output resistance. However, the parasitic capacitance in impedance 62 still causes time distortions in differential output signal VDIFF at 32. These time distortions are mainly due to asymmetric transients in the differential signals on output lines 32a and 32b. The asymmetric transients are the result of three factors working simultaneously: the non-linear responses of first and second transistors 44 and 46, the parasitic capacitance in impedance 62, and asymmetrically using input stage 40. The time distortions can be eliminated by removing one of these three factors and impedance 42 removes two of the three factors. Impedance 42 makes the behavior of converter 28 symmetrical and impedance 42 nullifies the common-mode output variation, which makes the output common-mode to differential conversion equal to zero. The time distortions are canceled by using a capacitive impedance value given by Equation I for impedance 42.

In operation of converter 28, which includes impedance 42, the gate of first transistor 44 receives the single-ended input signal VIN at 30 and the gate of second transistor 46 receives reference voltage VREF at 60. As the single-ended input signal VIN at 30 goes high, the common-node voltage VX at 56 transitions to a higher voltage level faster via impedance 42. As a result, first transistor 44 is biased on more slowly and second transistor 46 is biased off faster than in the case where impedance 42 is not present. Current source 52 sinks current IB that flows primarily through first impedance 48 and first transistor 44, such that the voltage on first output line 32a is less than the voltage on second output line 32b. As the single-ended input signal VIN at 30 goes low, the common-node voltage VX at 56 transitions to a lower voltage faster via impedance 42. As a result, first transistor 44 is biased off more slowly and second transistor 46 is biased on faster than in the case where impedance 42 is not present. Current source 52 sinks current IB that flows primarily through second impedance 50 and second transistor 46, such that the voltage on first output line 32a is more than the voltage on second output line 32b. The output differential signals in differential output signal VDIFF at 32 are substantially symmetric.

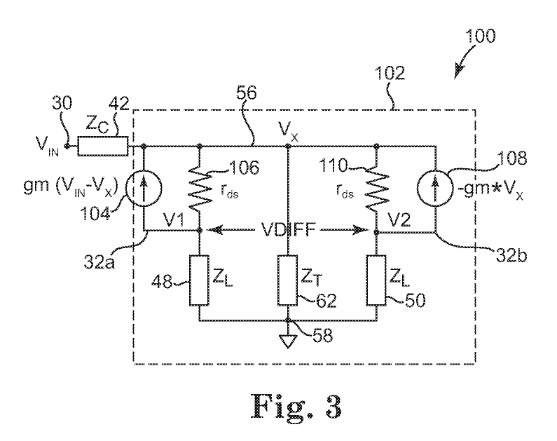

FIG. 3 is a diagram illustrating a small signal circuit 100 that is a small signal model of converter 28 of FIG. 2. Small signal circuit 100 includes an input stage small signal circuit 102 and impedance 42. Input stage small signal circuit 102 is a small signal model of input stage 40. Equation I is obtained via an analysis of small signal circuit 100.

Input stage small signal circuit 102 includes first load impedance 48, second load impedance 50, and current source impedance 62. Input stage small signal circuit 102 also includes a first transistor current source 104 and a first drain-source resistor 106, which model first transistor 44, and a second transistor current source 108 and a second drain-source resistor 110, which model second transistor 46. First transistor 44 and second transistor 46 each have trans-conductance gm. The value of the current from first transistor current source 104 is gm times (VIN−VX), where VIN is the single-ended input signal VIN at 30 and VX is the voltage on the common-node at 56. The value of the current from second transistor current source 108 is negative gm times VX.

In small signal circuit 100, one end of impedance 42 receives single-ended input signal VIN via input line 30 and the other end of impedance 42 is electrically coupled to the common-node via node line 56. Also, one end of each of first transistor current source 104, first drain-source resistor 106, second transistor current source 108, second drain-source resistor 110, and impedance 62 is electrically coupled to the common-node via node line 56. The other end of each of first transistor current source 104 and first drain-source resistor 106 is electrically coupled to one end of first load impedance 48 via first output line 32a, and the other end of each of the second transistor current source 108 and second drain-source resistor 110 is electrically coupled to one end of second load impedance 50 via second output line 32b. The other end of each of first load impedance 48, second load impedance 50, and impedance 62 is electrically coupled to the reference at 58.

To provide symmetric differential signals in differential output signal VDIFF at 32 and to nullify the common-mode output variation and make the output common-mode to differential conversion equal to zero, the value of impedance 42 is chosen to make the common-mode gain AC in Equation II equal to zero.

AC=(V1+V2)/VIN=0 Equation II

Where V1 is the output voltage at 32a, V2 is the output voltage at 32b, and VIN is the single-ended input signal VIN at 30.

A nodal analysis of the common-node at 56 results in Equation III, a nodal analysis of the node at 32a results in Equation IV, and a nodal analysis of the node at 32b results in Equation V.

VX/ZT+(V1+V2)/ZL=(VIN−Vx)/ZC Equation III

(Vx−V₁)/rds−gm(Vin−Vx)=V₁/ZL Equation IV

(Vx−V2)/rds+gm*Vx=V₂/ZL Equation V

Where VX is the voltage on the common-node at 56, ZT is the impedance of current source impedance 62, ZL is the impedance of each of the first and second impedances 48 and 50, ZC is the impedance of impedance 42, and rds is the resistance of each of the first drain-source resistor 106 and the second drain-source resistor 110.

Re-arranging Equation III results in Equation VI and summing Equations IV and V result in Equation VII.

VX(1/ZT+1/ZC)=VIN/ZC−(VD₁+V₂)/ZL Equation VI

(V₁+V₂)/ZL=2*Vx(gm+1/rds)−(V₁+V₂)/rds−gm*VIN Equation VII

Solving the above equations for the common mode gain AC results in Equation VIII.

AC=(2(1+gm*rds)ZT−gm*rds(ZT+ZC))/((ZL+rds)(ZT+ZC)+2*ZC*ZT(1+gm*rds)) Equation VIII

Thus, Equation IX is true for the common-mode gain AC to equal zero.

2(1+gm*rds)ZT−gm*rds(ZT+ZC)=0 Equation IX

Re-arranging equation IX results in Equation X and solving for ZC, impedance 42, results in Equation XI, which is the same as Equation I.

(2+gm*rds)ZT=gm*rds*ZC Equation X

Zc=ZT(1+2/(gm*rds)) Equation XI

Impedance 42 receives the single-ended input signal VIN at 30 and provides compensation to the common-node at 56 based on the single-ended input signal VIN at 30. Impedance 42 provides compensation to provide symmetric differential signals in differential output signal VDIFF at 32. Impedance 42 nullifies the common-mode output variation and makes the output common-mode to differential conversion equal to zero. Impedance 42 makes the common-mode gain AC equal to zero, which cancels the amplitude and time distortions in differential output signal 32. With impedance 42, converter 28 is suitable for high-speed applications.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
an input stage configured to receive a single-ended input signal and provide a differential output signal; and
an impedance configured to receive the single-ended input signal and provide compensation to the input stage to provide symmetrical differential signals in the differential output signal.

2. The integrated circuit of claim 1, wherein the input stage comprises:
a differential pair of transistors having a common node and the impedance is configured to provide compensation to the common node.

3. The integrated circuit of claim 2, wherein the input stage comprises:
a first input that receives the single-ended input signal and a second input that receives a reference signal.

4. The integrated circuit of claim 3, wherein the impedance is coupled between the first input and the common node.

5. The integrated circuit of claim 2, wherein the input stage comprises:
a current source configured to provide current to the differential pair of transistors via the common node.

6. The integrated circuit of claim 1, wherein the impedance is capacitive.

7. The integrated circuit of claim 1, wherein the impedance makes the conversion from common-mode input to the differential output signal substantially equal to zero.

8. A system comprising:
an input stage configured to receive a single-ended input signal and provide a differential output signal; and
an impedance configured to receive the single-ended input signal and provide compensation to the input stage to nullify common-mode variations in the differential output signal.

9. The system of claim 8, wherein the input stage comprises:
a differential pair of transistors having a common node and the impedance is configured to provide compensation to the common node.

10. The system of claim 9, wherein the input stage comprises:
an input that receives the single-ended input signal and the impedance is coupled at one end to the input and at the other end to the common node.

11. The system of claim 10, wherein the input stage comprises:
a current source configured to provide current to the differential pair of transistors via the common node.

12. An integrated circuit comprising:
means for receiving a single-ended input signal;
means for providing a differential output signal based on the single-ended input signal; and
means for providing compensation based on the single-ended input signal to the means for providing a differential output signal to provide symmetrical differential signals in the differential output signal.

13. The integrated circuit of claim 12, wherein the means for providing compensation comprises;
means for providing compensation based on the single-ended input signal to the means for providing a differential output signal to nullify common-mode variations in the differential output signal.

14. The integrated circuit of claim 12, wherein:
the means for providing a differential output signal comprises:
means for switching that has a common node; and
means for providing a current to the common node; and
the means for providing compensation comprises:
means for providing compensation to the common node.

15. A method of converting a single-ended input signal to a differential output signal, comprising:
receiving the single-ended input signal via a differential pair of transistors;
providing the differential output signal based on the single-ended input signal; and
providing compensation based on the single-ended input signal to the differential pair of transistors to provide symmetrical differential signals in the differential output signal.

16. The method of claim 15, wherein providing compensation comprises;
providing compensation based on the single-ended input signal to nullify common-mode variations in the differential output signal.

17. The method of claim 15, wherein providing the differential output signal comprises:
providing a current to a common node of the differential pair of transistors.

18. The method of claim 15, wherein providing compensation comprises:
providing compensation to a common node of the differential pair of transistors.

19. The method of claim 15, wherein providing the differential output signal comprises:
providing a current at a common node of the differential pair of transistors.

20. A method of converting a single-ended input signal to a differential output signal, comprising:
receiving the single-ended input signal;
providing the differential output signal; and
providing compensation based on the single-ended input signal to nullify common-mode variations in the differential output signal.

21. The method of claim 20, wherein providing the differential output signal comprises:
switching a differential pair of transistors.

22. The method of claim 21, wherein providing compensation comprises:
providing compensation to a common node of the differential pair of transistors.
